(19) United States
(12) Patent Application Publication
(10) Pub. No.: US 2014/0305494 A1
(43) Pub. Date: Oct. 16, 2014

(54) HEADER STRUCTURES FOR FLEXIBLE PHOTOVOLTAIC MODULES

(71) Applicant: Apollo Precision (Fujian) Limited, Fujian (CN)

(72) Inventor: Tanya Dhir, Santa Clara, CA (US)

(73) Assignee: Apollo Precision (Fujian) Limited, Fujian (CN)

(21) Appl. No.: 14/252,282

(22) Filed: Apr. 14, 2014

Related U.S. Application Data
(60) Provisional application No. 61/811,419, filed on Apr. 12, 2013.

(51) Int. Cl. H02S 30/20

(52) U.S. Cl. CPC H01L 31/045
USPC 136/251

(57) ABSTRACT

Provided are flexible photovoltaic modules having header structures for protecting, reinforcing, and sealing edges formed by sealing sheets of the modules. A flexible module may include one or more header structures. In certain embodiments, two header structures are provided on the same edge or two opposite edges of the module. A header structure may enclose a portion of the edge or the entire edge. A header structure may be a sleeve enclosing an edge formed by two sealing sheets. In other embodiment, in which an edge is formed by only one shorter sealing sheet, a header structure may extend over this edge. A header structure may enclose one or more electrical leads protruding from a sealed space formed by the sealing sheets. These electrical leads may be connected to conductive elements provided within the header structure and used for establishing electrical connections to other components of the photovoltaic array.

### CROSS-REFERENCE TO RELATED APPLICATION

This application claims the benefit of priority to U.S. Provisional Application No. 61/811,419, titled “HEADER STRUCTURES FOR FLEXIBLE PHOTOVOLTAIC MODULES,” filed Apr. 12, 2013, all of which is incorporated herein by reference in its entirety and for all purposes.

### BACKGROUND

Photovoltaic technology is being rapidly adopted to generate electricity from solar energy, both for local use and for supplying power to electrical grids. Photovoltaic systems may be implemented on vehicles, on buildings, or as standalone photovoltaic arrays. Photovoltaic cells are the basic units of such systems. One or more photovoltaic cells are typically arranged into a photovoltaic module, which may be then used to form a photovoltaic array.

### SUMMARY

Provided are flexible photovoltaic modules having header structures for protecting, reinforcing, and sealing edges formed by sealing sheets of the modules. A flexible module may include one or more header structures. The header structures can various configurations. For example, in certain embodiments, two header structures are provided on the same edge or two opposite edges of the module. A header structure may enclose or extend over a portion of an edge or the entire edge. In some embodiments, a header structure may include a sleeve enclosing or extending over an edge formed by two sealing sheets. In some embodiments, a header structure may enclose or extend over an edge formed by a single sealing sheet. A header structure may enclose or extend over one or more electrical leads protruding from a sealed space formed by the sealing sheets. These electrical leads may be connected to conductive elements provided within the header structure and be configured to establish electrical connections to other components of a photovoltaic array.

These and other embodiments are described further below with reference to the figures.

### BRIEF DESCRIPTION OF THE DRAWINGS

FIGS. 1A and 1B are top and side schematic views of a flexible photovoltaic module having a header structure enclosing and extending along an entire edge formed by two sealing sheets, in accordance with certain embodiments.

FIG. 2 is a side schematic view of a flexible photovoltaic module having a header structure enclosing an edge formed by only one shorter sealing sheet, in accordance with certain embodiments.

FIG. 3 is a top schematic view of a flexible photovoltaic module having a header structure extending over a portion of an edge, in accordance with certain embodiments.

FIGS. 4A and 4B are top and side schematic views of a flexible photovoltaic module having two header structures provided on opposite edges of the module, in accordance with certain embodiments.

FIG. 5A is a top schematic view of a flexible photovoltaic module having a header structure supporting a junction box for interconnecting multiple electrical leads of the module, in accordance with certain embodiments.

FIG. 5B is a top schematic view of a flexible photovoltaic module with its electrical leads interconnected within a junction box supported by the header structure of the module, in accordance with certain embodiments.

FIG. 5C is an expanded view of the junction box from FIG. 5B illustrating electrical connections made with the electrical leads of the module, in accordance with certain embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily Obscure the described concepts. While some concepts will be described in conjunction with the specific embodiments, it will be understood that these embodiments are not intended to be limiting.

### Introduction

Flexible photovoltaic modules include flexible sealing sheets and flexible photovoltaic cells sealed in between these sheets. Use of such flexible components allows these modules to bend to a certain extent during handling and installation. Furthermore, flexible photovoltaic modules may be installed on surfaces that are not perfectly flat and have some topographical variations.

Flexible materials may also facilitate cutting, bending, or otherwise forming and modifying to fit the available installation areas. Flexible polymeric sealing sheets may allow for various options for attaching the sealing sheets to installation surfaces such as polymer membranes on the rooftops of commercial buildings. For example, a flexible module may be welded to, or otherwise attached and sealed with respect to, a rooftop membrane around the edges of the module to prevent water and other environmental objects from getting in between the module and membrane. Examples of installation surfaces for flexible modules include ethylene propylene diene monomer (EPDM), chlorosulfonated polyethylene (CSF), polyvinyl chloride (PVC), and thermoplastic polyolefin (TPO).

While the flexible modules described herein can facilitate installation, they also present some challenges during installation and operation, such as forming and maintaining seals at various interfaces that may be subject to bending. For example, one challenge may be sealing the interface where electrical leads extend from a sealed area formed by the flexible sealing sheets. Another challenge may be providing adequate support to various components of the module. For example, conductive elements may not be adequately supported by flexible materials.

Flexible photovoltaic modules described herein may include header structures that reinforce edges of the modules. In certain embodiments, these edges include sealing interfaces between sealing sheets of the modules. A sealing interface, or other module edge, may coincide with edges of one or two sealing sheets of the module. For example, both sealing sheets may extend to a certain position forming a common edge; the sealing interface coinciding with the common edge. In some other embodiments, one sealing sheet may be longer than the other, with the sealing interface corresponding to the edge of the shorter sheet. In certain embodiments, the shorter sealing sheet is a front side sealing sheet of the flexible module.

A header structure may reinforce an entire edge or less than the entire edge, according to various embodiments. For example, a header structure may reinforce portions of an edge where one or more electrical leads extend from the sealed space. The remaining portions of the edge may remain unreinforced. A header structure may add some rigidity to at least the reinforced portion of the edge and prevent bending of this portion. The rigidity may help preserve sealing characteristics of the sealing interface, particularly when other components extend through this interface.

A flexible photovoltaic module may include one or more header structures. Multiple header structures may be positioned along the same or different edges. For example, one edge may include two header structures. These header structures may be positioned on the opposite ends of this edge. Each of these header structures may include its own module connector configured to connect to an external connection point, for example, to an adjacent flexible module. In some other embodiments, one header structure may be provided on one edge of the module, while another header structure may be provided on an adjacent or opposite edge of the module. Likewise, each one of these header structures may include its own module connector for connecting to adjacent flexible modules or other electrical components of the array.

A module connector of the header structure includes one or more conductive elements. At least one of these conductive elements may be connected to the photovoltaic cells of this module or be configured to be connected to the photovoltaic cells during installation of the module. In certain embodiments, a module includes two module connectors provided in the same or different header structures. Each of the two module connectors may have a conductive element connected, or configured to be connected, to the photovoltaic cells. The two conductive elements, each one provided in a different module connector, may have different polarities. In certain embodiments, a single module connector can include two conductive elements connected or configured to be connected to the photovoltaic cells.

In some embodiments, to ensure electrical safety, conductive elements may be embedded within insulating enclosures. These enclosures prevent installers and handlers from accidentally touching the conductive elements. In the same or other embodiments, flexible modules may be fabricated with conductive elements disconnected from the photovoltaic cells. The conductive elements can be configured to be connected to the photovoltaic cells during the installation process. In certain embodiments, the conductive elements may remain disconnected even during initial installation operations. Flexible modules including disconnected conductive elements may include electronic control units and/or junction boxes for establishing electrical connections between the photovoltaic cells and conductive elements prior to operation.

### Flexible Photovoltaic Module Examples

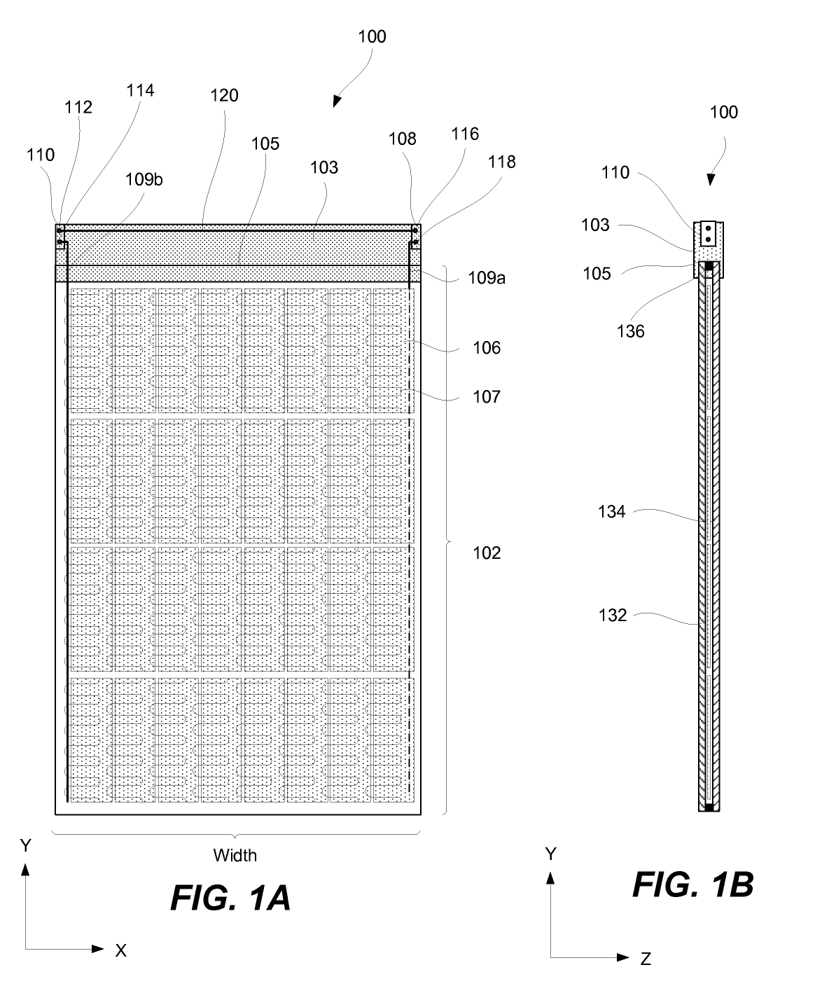

FIGS. 1A and 1B are top and side schematic views of flexible photovoltaic module 100 having header structure 103 attached to front side flexible sealing sheet 132 and back side flexible sealing sheet 134, in accordance with certain embodiments. Sealing sheets 132 and 134 are sealed together to form a sealed space 102 and an edge 105. Edge 105 is enclosed by header structure 103 as shown in FIG. 1B. In this example, header structure 103 extends over the entire width of module 100 as shown in FIG. 1A.

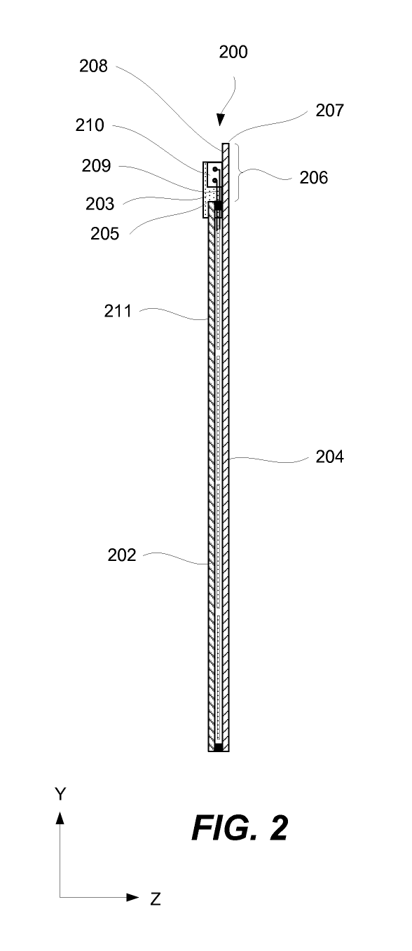

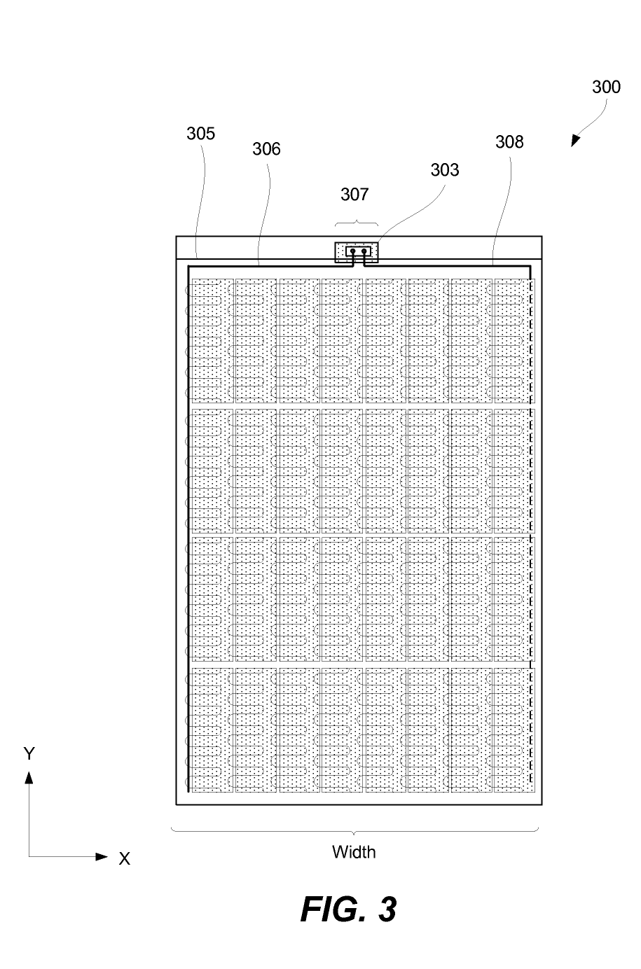

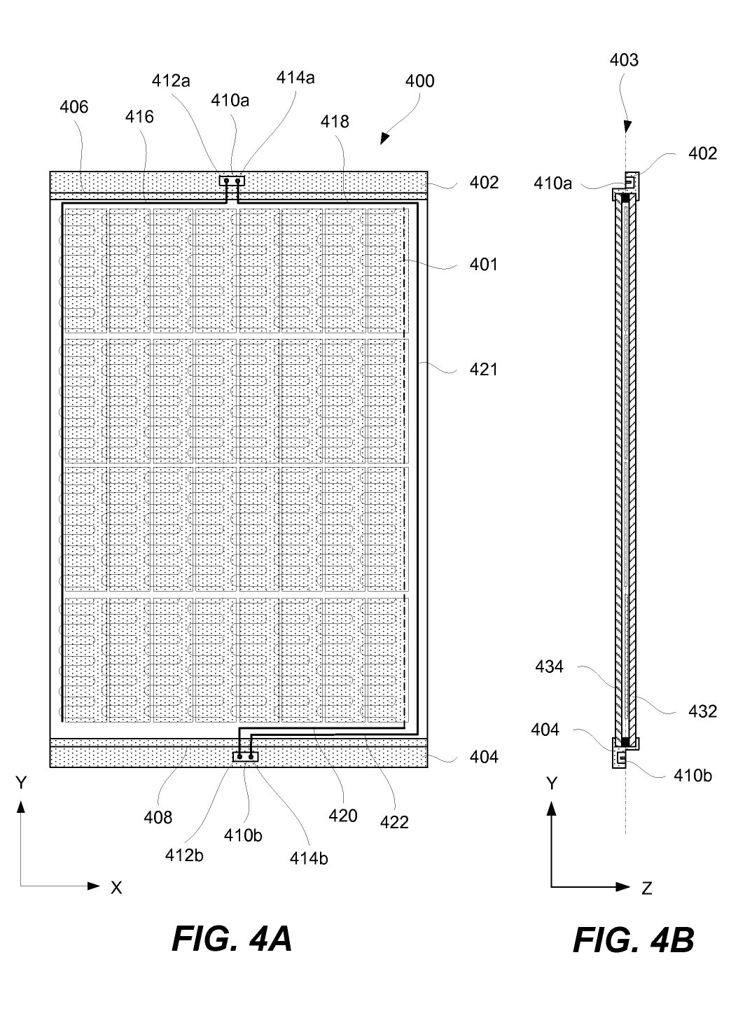

In other embodiments, a header structure may also enclose an edge formed by only one sheet, as further explained below with reference to FIG. 2. A header structure may also be used to enclose only a portion of the edge, as further explained below with reference to FIG. 3. Furthermore, a module may have multiple header structures enclosing portions of the same edge or different edges of the module. One such example is further explained below with reference FIGS. 4A and 4B.

Returning to FIGS. 1A and 1B, header structure 103 may enclose one or more electrical leads 109a and 109b protruding through edge 105. These electrical leads 109a and 109b protrude from sealed space 102 and into header structure 103. Electricals leads 109a and 109b may be bus bars or other suitable flat structures that allow them to extend through the sealing interface without interfering with this interface. In addition to enclosing electrical components, header structure 103 can provide sealing and mechanical support of edge 105. In some embodiments, a header structure does not include or enclose any electrical components.

A portion of header structure 103 may overlap with sealed space 102. Sealed space 102 houses and protects photovoltaic cells 106 from the environment. Sealed space 102 may be defined by an overlap of two sealing sheets 132 and 134. For example, two sealing sheets 132 and 134 having the same size and that are sealed around their edges such that their boundaries coincide as, for example, shown in FIG. 1A, can define a sealed space 102 having a boundary that coincides with the boundaries of sealing sheets 132 and 134. In some other embodiments, two sealing sheets may not be sealed around their edges. For example, a seal may be positioned within the boundaries of the sealing sheets at a distance from the perimeter of one or both sealing sheets. In these embodiments, the sealing space may be defined by the position of the seal. In other embodiments further described below with reference to FIG. 2, one sealing sheet is longer than another sealing sheet. The longer sealing sheet may extend past the edge enclosed by a header structure.

Flexible photovoltaic module 100 may also include edge seal 136 that surrounds photovoltaic cells 106 and forms a sealed space with flexible sealing sheets 132 and 134. Edge seal 136 may prevent moisture from penetrating and reaching cells 106. Edge seal 136 may be made from certain organic or inorganic materials that have low inherent water vapor transmission rates. In certain embodiments, edge seal 136 is configured to absorb moisture from inside the module in addition to protecting the module from moisture ingression. For example, a butyl-rubber containing moisture getter or desiccant may be used to form edge seal 136. In certain embodiments, a portion of the edge seal 136 that contacts electrical components (e.g., bus bars) of module 100 is made from a thermally resistant polymeric material. Edge seal 136 may be also used to secure front side sealing sheet 132 with respect to back side sealing sheet 134. In certain embodiments, edge seal 136 determines the boundaries of sealed space 102.

The overlap between header structure 103 and sealed space 102 may be formed by extending portions of two sealing sheets 132 and 134 into header structure 103 as, for example, illustrated in FIG. 1B. In these embodiments, header structure 103 may provide additional support to the seal. In other embodiments further described below with reference to FIG. 2, an overlap may be formed by extending a header structure over an edge forming by one sheet only. In certain embodiments, there is no overlap between a header structure and sealed space. For example, a sealing interface may extend parallel to a header structure without any overlap between the two.

Returning to FIGS. 1A and 1B, flexible photovoltaic module 100 includes one or more flexible photovoltaic cells 106 provided in sealed space 102 between sealing sheets 132 and 134. Examples of flexible photovoltaic cells include copper indium gallium selenide (CIGS) cells, cadmium-telluride (Cd—Te) cells, amorphous silicon (a-Si) cells, microcrystalline silicon (Si) cells, crystalline silicon (c-Si) cells, gallium arsenide (GaAs) multi-junction cells, light adsorbing dye cells, organic polymer cells, and other types of photovoltaic cells. A photovoltaic cell typically has a photovoltaic layer that generates a voltage when exposed to light. The photovoltaic layer may be positioned adjacent to a back conductive layer, which, in certain embodiments, is a thin flexible layer of molybdenum, niobium, copper, and/or silver. The photovoltaic cell may also include a flexible conductive substrate, such as stainless steel foil, titanium foil, copper foil, aluminum foil, or beryllium foil. Another example includes a conductive oxide or metallic deposition over a polymer film, such as polyimide. In certain embodiments, a substrate has a thickness of between about 2 mils and 50 mils, e.g., about 10 mils, with other thicknesses also in the scope of the embodiments described herein. The photovoltaic cell may also include atop flexible conductive layer. This layer typically includes one or more transparent conductive oxides (TCO), such as zinc oxide, aluminum doped zinc oxide (AZO), indium tin oxide (ITO), and gallium doped zinc oxide. A typical thickness of a top conductive layer is between about 100 nanometers and 1,000 nanometers or, more specifically, about 200 nanometers and 800 nanometers.

Photovoltaic cells 106 may be interconnected using one or more wire networks 107. A wire network 107 may extend over a front side of one cell as well as over a back side of another, adjacent cell to interconnect these two cells in series as shown in FIGS. 1A and 1B. Module 100 is shown to have four sets of photovoltaic cells 106. Each set includes eight cells interconnected in series by wire networks 107. The four sets are interconnected in parallel by electrical leads 109a and 109b. Electrical leads 109a and 109b are connected to conductive elements 114 and 118, respectively. While FIG. 1A shows an example of a flexible photovoltaic module, one having ordinary skill in the art will understand that a flexible photovoltaic module may include any number of photovoltaic cells. Moreover, the photovoltaic cells may be arranged and interconnected in any appropriate fashion using any appropriate electrical connector in addition to or instead of wire networks and bus bars. The example shown in FIGS. 1A and 1B is for illustrative purposes only and is not intended to be limiting.

Flexible sealing sheets 132 and 134 may include flexible materials such as polyethylene, polyethylene terephthalate (PET), polypropylene, polybutylene, polybutylene terephthalate (PBT), polyphenylene oxide (PPO), polyphenylene sulfide (PPS) polystyrene, polycarbonates (PC), ethylene-vinyl acetate (EVA), fluoropolymers (e.g., polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE)), acrylics (e.g., poly(methyl methacrylate)), silicones (e.g., silicone polyesters), and/or PVC, as well as multilayer laminates and co-extrusions of these materials. A typical thickness of a sealing sheet is between about 5 mils and 100 mils or, for example, between about 10 mils and 50 mils. In certain embodiments, a sealing sheet includes a metallized layer to improve its water permeability characteristics. For example, a metal foil may be positioned in between two insulating layers to form a composite back side sealing sheet.

In certain embodiments, flexible photovoltaic module 100 has an encapsulant layer positioned between front side sealing sheet 132 and photovoltaic cells 106. Another encapsulant layer may be provided between back side sealing sheet 134 and photovoltaic cells 106. Examples of encapsulant layer materials include non-olefin TPO, such as polyethylene polypropylene, polybutylene, polyethylene terephthalate, polybutylene terephthalate, polystyrene, polycarbonates, fluoropolymers, acrylics, ionomers, silicones, and combinations thereof. In some embodiments, an encapsulant includes a linear low density polymer such as a linear low density polyethylene.

A header structure may ay include one or more module connectors. Specifically, FIG. 1A illustrates header structure 103 having two module connectors 108 and 110 positioned on opposite ends (in the X direction) of header structure 103. In other embodiments, a header structure has only one module connector as shown, for example, in FIG. 3. Furthermore, a header structure may have no module connectors. For example, module connectors may be provided in another location of the module away from the header structures. Such header structures may still enclose electrical leads protruding through the edge. These leads may extend to other module components that include module connectors or other electrical components.

A module connector may include one or more conductive elements. A total number of conductive elements in the module connector may vary. In certain embodiments, a module connector includes two conductive elements. In some embodiments, both of these conductive elements may be connected to the photovoltaic cells of the module. In some other embodiments, one of these elements may be connected to the photovoltaic cells of the module, while another one may be connected return line.

FIG. 1A illustrates flexible photovoltaic module 100 including two module connectors 108 and 110 that together house four conductive elements 112, 114, 116, and 118. Specifically, module connector 108 includes conductive elements 116 and 118, while module connector 110 includes conductive elements 112 and 114. Conductive elements 112 and 116 are shown connected to return line 120 and, therefore, are in electronic communication with each other. Conductive elements 114 and 118 are shown connected to flexible photovoltaic cells 106 and may have different polarities.

FIG. 2 illustrates a module 200 having back side sealing sheet 204 that is longer than front side sealing sheet 202, in accordance with certain embodiments. Specifically, back side sealing sheet 204 extends past edge 205 of front side sealing sheet 202 in the Y direction. The portion of back side sealing sheet 204 that extends beyond edge 205 may be referred to as flap 206.

Header structure 203 encloses edge 205 by extending over front surface 211 of front side sealing sheet 202 and over front surface 208 of flap 206. Header structure 203 may be mechanically attached to and, in certain embodiments, sealed with respect to both surfaces 211 and 208. Header structure 203 may or may not extend to edge 207 of back side sealing sheet 204. A mechanical attachment between header structure 203 and one or both sealing sheets 202 and 204 supports these components with respect to each other. Furthermore, header structure 203 may add rigidity to edge 205 and provide protection to this edge during handling, installation, and operation of module 200. Mechanical attachment may be provided by adhering header structure 203 to one or both sealing sheets 202 and 20.4 using an adhesive or some other bonding components, molding header structure 203 over one or both sealing sheets 202 and 204, using mechanical fasteners, and other attachment methods.

In certain embodiments, header structure 203 may be sealed with respect to both sealing sheets 202 and 204 or, more specifically, with respect to their front light incident surfaces 211 and 208. This sealing may help to establish and/or improve the sealing interface between sealing sheets 202 and 204. In more specific embodiments, there may be no sealing feature between sealing sheets 202 and 204 other than header structure 203. These mechanical attachment and sealing features may be applied to various other embodiments of header structures, such as an enclosing header structure described above with reference to FIGS. 1A and 1B.

Header structure 203 may also support module connector 210. Specifically, header structure 203 may attach module connector 210 to front side sealing sheet 202 and/or back side sealing sheet 204. In certain embodiments, module connector 210 is integrated into header structure 203. For example, module connector 210 may be partially or fay enclosed by header structure 203 or may be monolithic with header structure 203. Further, header structure 203 may support and insulate electrical leads 209 protruding between edge 205 and module connector 210. In certain embodiments, module connector 210 is not attached to header structure and may be, for example, independently attached to back side sealing sheet 204.

In certain embodiments (not shown), a header structure may enclose sealing sheet edges that do not coincide with each other. For example, an edge of the back side sealing sheet may protrude past the edge of the front side sealing sheet by a certain distance, thereby forming a flap. To form this enclosure, the width of the header structure may be greater than the width of this flap. As such, the header structure extends and encloses edges of both sealing sheets.

A header structure may be made from one or more rigid materials such as polyethylene terephthalate (e.g., RYNITE® available from Du Pont in Wilmington, Del.), polybutylene terephthalate (e.g., CRASTIN® also available from Du Pont), nylon in any of its engineered formulations of Nylon 6 and Nylon 66, polyphenylene sulfide (e.g., RYTON® available from Chevron Phillips in The Woodlands, Tex.), polyamide (e.g., ZYTEL® available from DuPont), polycarbonate (PC), polyester (PE), polypropylene (PP), PVC and weatherable engineering thermoplastics such as polyphenylene oxide (PP(l), polymethyl methacrylate, polyphenylene (PPE), styrene-acrylonitrile (SAN), polystyrene, and blends based on those materials. Furthermore, weatherable thermosetting polymers, such as unsaturated polyester (UP) and epoxy, may be used. Other examples include engineered polymers formulated to meet certain requirements specific to photovoltaic applications. For example, certain hybrid block co-polymers may be used. These materials meet specific requirements of photovoltaic applications, such as temperature variation stability, moisture stability, ultra violet (UV) stability, and the like. In specific embodiments, a header structure is made from one or more of the following polymers: polyethylene terephthalate, polybutylene terephthalate, polyphenylene sulfide, and polyamide.

To maintain electrical connections with adjacent modules and other electrical components of an array, a flexible photovoltaic module may have one or more interlocking features. An interlocking feature is a feature that interlocks with another interlocking feature. Examples of interlocking fixtures include various recess-protrusion combinations such as plugs and sockets. Additional interlocking features examples can include latches and threads. Such interlocking features may be provided on header structures or on module connectors supported by header structures. In certain embodiments, an entire header structure may be a part of an interlocking feature. For example, the entire header structure or some of its components, such as a connector body, may be shaped as a plug that fits into a socket of another component, such as a socket formed by a header structure of an adjacent module. Once the two interlocking fixtures are engaged during the installation, the mechanical connection and, in certain embodiments, one or more electrical connections are maintained. Interlocking features can prevent unintended disengagement of module components during operation, which may be caused by thermal expansion and contraction of the flexible modules, external forces, such as freezing and thawing of residual moisture on the roof top, and other causes.

In certain embodiments, a header structure does not extend along an entire edge of a flexible module, enclosing only a portion of the edge. FIG. 3 is a top schematic view of flexible photovoltaic module 300 having a header structure 303 enclosing portion 307 of edge 305, in accordance with certain embodiments. In these embodiments, the length of header structure 303 is shorter than the length of edge 305. Enclosing only a portion of edge 305 may be sufficient to enclose electrical leads 306 and 308, which extend through edge 305. In specific embodiments, header structure 303 may enclose less than about 25% of edge 305, less than about 10% or even less than about 5%. This ratio may be determined, for example, by the size, number, and relative positions of the electrical leads.

When header structure 303 is shorter than the edge 305 and does not enclose the entire edge 305, the header structure 303 may be positioned at any location along the length of edge 305. FIG. 3 illustrates header structure 303 positioned substantially in the middle of edge 305. In other embodiments (not shown), a partially-enclosing header structure may be positioned on one end of the edge. In one example of multiple header structures provided on the same edge, one structure may be provided on one end of the edge, while another structure may be provided on the other end of the edge.

Flexible Photovoltaic Modules with Multiple Header Structures

FIGS. 4A and 4B are top and side schematic views of flexible photovoltaic module 400 having two header structures 402 and 404, in accordance with certain embodiments. In this example, header structure 402 encloses edge 406, while header structure 404 encloses edge 408. Two edges enclosed by headers structures may be opposite edges as shown in FIGS. 4A and 4B or adjacent edges. Furthermore, multiple header structures may enclose three, four, or even more edges of a flexible photovoltaic module. Header structures enclosing opposite edges may be positioned along shorter edges of a rectangular module (as shown in FIG. 4A) or along longer edges.

Header structures 402 and 404 may be designed to overlap and connect to other header structures, for example, to header structures of adjacent flexible photovoltaic modules or to bodies of external connectors. FIG. 4B illustrates header structure 402 shifted in the Z direction from center line 403 and header structure 404 shifted in the opposite direction from center line 403. Center line 403 may be defined by a plane positioned substantially equidistant from and between front side sealing sheet 432 and back side sealing sheet 434. In this example, module connectors 410a and 410b are positioned such that their conductive elements face center line 403. During installation of module 400, another connector may be attached to module connector 410a such that this other connector is positioned on the other side of center line 403 with respect to module connector 410a. Similarly, a connector may be attached to module connector 410b such that the attached connectors are on opposite sides of center line 403.

Various internal connection schemes may be used to interconnect conductive elements of module connectors and photovoltaic cells. Depending on these internal connection schemes, adjacent modules may be connected in series, in parallel, or according to various other designs. FIG. 4A illustrates an example where module 400 is configured to connect in series with other similar modules installed adjacent to module 400. Module connector 410a provided on header structure 402 includes two conductive elements 412a and 414a. Element 412a is connected to photovoltaic cells 401 by electrical lead 416. Element 414a is connected to return line 421 by electrical lead 418. Header structure 402 encloses electrical leads 416 and 418 at the point where these leads protrude through edge 406. Header structure 402 also provides sealing and mechanical support to an interface between two sealing sheets 432 and 434 at edge 406 around electrical leads 416 and 418. In a similar manner, module connector 410b provided on header structure 404 includes two conductive elements 412b and 414b. Element 412b is connected to photovoltaic cells 401 using electrical lead 420. However, a polarity of conductive element 412b is different (opposite) from a polarity of conductive element 412b of module connector 410a. Element 414b is connected to return line 421 using electrical lead 422. Therefore, elements 414a and 414b are interconnected. Header structure 404 encloses electrical leads 420 and 422, which protrude through edge 408, and provides sealing and mechanical support to this other interface.

### Electrical Safety and Configuration Features

When photovoltaic cells of a module are exposed to light, these cells may apply voltage to various conductive components of the module. This may occur prior to or during installation of the module. If conductive elements of a module are connected to the cells, it may present some safety concerns. To address these concerns, conductive elements may be enclosed in insulating bodies that prevent accidental contact but still allow for establishing electrical connections with other conductive elements. However, such insulating bodies may result in very thick connector bodies, with thickness being shown in the Z direction in FIG. 1B, for example. Excessive thickness of the connector bodies may cause a tripping hazard when rooftops are used as walkways and/or difficulties with sealing adjacent modules.

In certain embodiments, one or more conductive elements of a module are disconnected from its photovoltaic cells prior to and during initial installation operations. For example, conductive elements may remain disconnected from the cells until these elements become inaccessible, such as when they become connected to other external electrical components. At some point during installation, these conductive elements are connected to the cells to provide a fully operational module. These connections between the cells and conductive elements may be established by installing or rearranging bridging connectors in a junction box provided in the module. The junction box may be made accessible after the module is physically installed on the supporting surface. In the same or other embodiments, connections between the cells and conductive elements may be established using an electronic control unit, which may respond to a certain signal to establish the connections. In certain embodiments, these electrical safety features may be a part of a module connector.

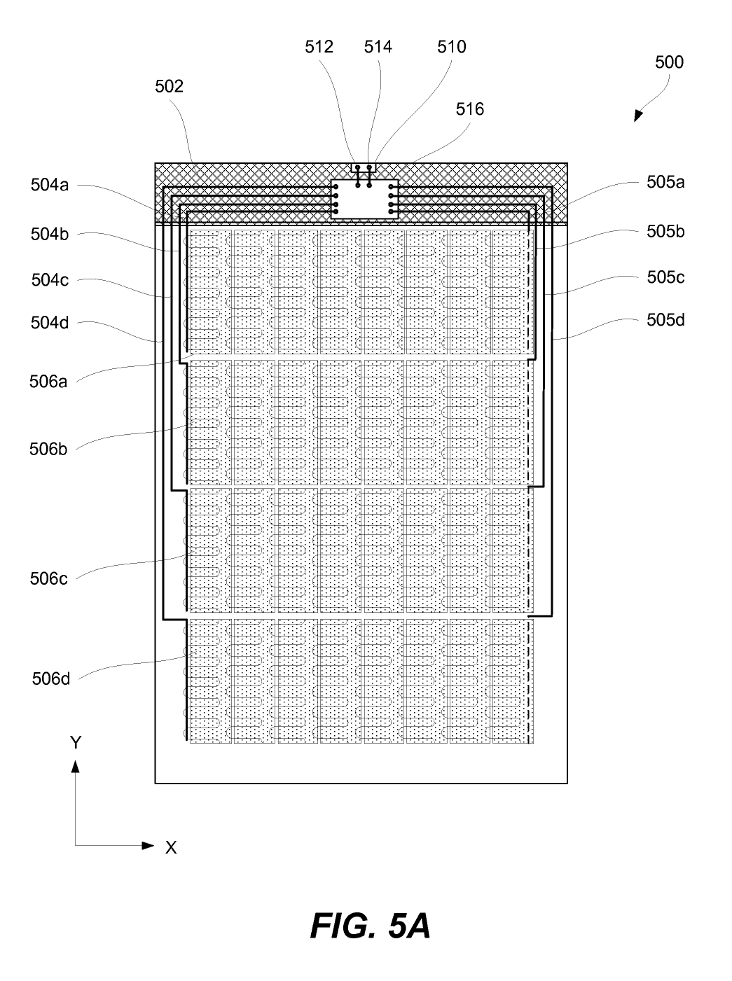

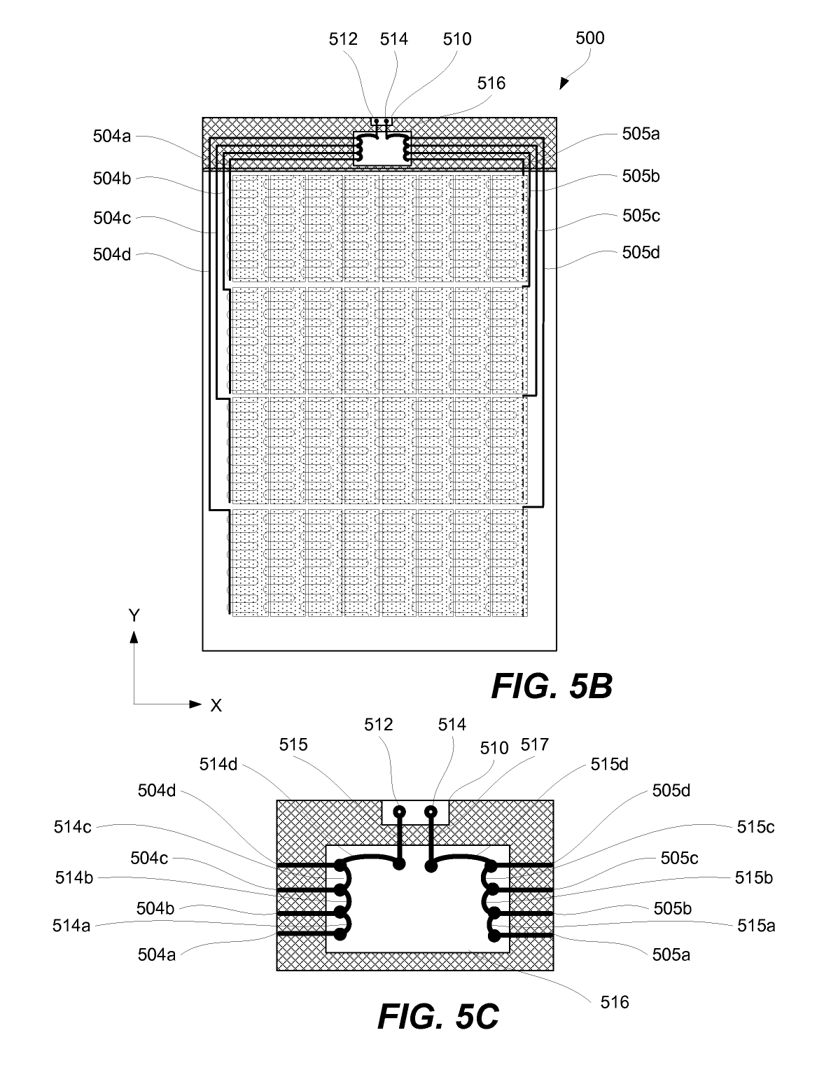

FIG. 5A is a schematic view of flexible photovoltaic module 500 including junction box 516 supported by header structure 502 with photovoltaic cell lead lines 504a-504d and 505a-505d disconnected from conductive elements 512 and 514 of module connector 510, in accordance with certain embodiments. Flexible photovoltaic module 500 includes four sets of photovoltaic cells 506a-506d each having a pair of lead lines (i.e., set 506a has lead lines 504a and 505a, set 506b has lead lines 504b and 505b, set 506c has lead lines 504c and 505c, and set 506d has lead lines 504d and 505d). Lead lines 504a-504d have a different polarity with respect to lead lines 505a-505d. Photovoltaic cells are interconnected in series in each set. One having ordinary skill in the art would understand that other cell arrangements with flexible modules are possible. For example, photovoltaic cells may be interconnected in parallel in each other.

Flexible photovoltaic module 500 may be manufactured in the state shown in FIG. 5A. Further, module 500 may be kept in that state until installation and even during some initial installation operations. As such, even if photovoltaic cells 506a-506d are exposed to light during the handling and installation of photovoltaic module 500, the voltage will not be applied to conductive elements 512 and 514 of module connector 510. In certain embodiments, photovoltaic cell lead lines 504a-504d and 505a-505d are interconnected with each other during manufacturing but are still disconnected from conductive elements 512 and 514 of module connector 510.

FIG. 5B is a schematic view of flexible photovoltaic module 500 with photovoltaic cell lead lines 504a-504d and 505a-505d connected to conductive elements 512 and 514 of module connector 510, in accordance with certain embodiments. Junction box 516 may be accessed to install various bridging connectors, which will now be explained with reference to FIG. 5C illustrating an expanded view of junction box 516 after connections have been completed. Cell lead lines 504a-504d are interconnected with bridging connectors 514a-514c. Cell lead lines 505a-505d are interconnected with bridging connectors 515a-515c. In this embodiment, photovoltaic cell sets 506a-506d are interconnected in series. However, other connection schemes are possible as well. Interconnected cell lead lines 504a-504d are also connected to conductive element lead line 515 (or directly to conductive element 512) using bridging connector 514d. In a similar manner, interconnected cell lead lines 505a-505d are connected to conductive element lead line 517 (or directly to conductive element 514) using bridging connector 515d.

In certain embodiments, multiple bridging connectors are integrated into a single physical component, which, for example, may be plugged into a socket provided in the junction box during one of the installation operations. In certain embodiments, one or more bridging connectors may be provided in junction box 516 during module fabrication. However, these bridging connectors do not make electrical connections between cell lead lines 504a-504d and conductive element 512 or between cell lead lines 505a-505d and conductive element 514. During installation, these bridging connectors are reoriented to provide necessary connections.

Prior to forming the electrical connections shown in FIGS. 5B and 5C, conductive elements 512 and 514 may be connected to other conductive elements, such as conductive elements of another module connector or conductive elements of a jumper connector. For purposes of this document, a jumper connector is defined as a component that electrically interconnects two or more conductive elements of the same module connector. For example, multiple flexible photovoltaic modules may be interconnected in series to form a string of interconnected modules. Two modules in this string represent end modules and are connected to only one other module in the string. All other modules are connected to two other (e.g., adjacent) modules in the string. One end module may be connected to an inverter or some other electrical component of the array. Another end module may have its return line interconnected with photovoltaic cells at its end that is not connected to another module. Sometimes this interconnection is performed by attaching a jumper to this end or, more specifically, to a module connector at this free end. In other embodiments, this interconnection can be made within junction box 516 (for example, by interconnecting leads 514d and 515d). In this example, conductive elements 512 and 514 remain unconnected to external conductive elements.

In certain embodiments, a flexible photovoltaic module includes an electronic control unit configured to establish an electrical connection at some point during installation between a conductive element of the module connector and one or more photovoltaic cells. For example, the control unit may keep the conductive element disconnected from the one or more photovoltaic cells until a predetermined signal is received during installation. Once the signal is received, the connection is provided. The signal may be supplied wirelessly or though already established electrical connections in the module. The electrical connections established by the electronic control unit may be similar to the ones described above with reference to FIGS. 5A-5C.

Flexible photovoltaic module 500 may also include bypass diodes, inverters, DC/DC converters, and various combinations of these components (not shown in FIGS. 5A-5C). A bypass diode can be configured to prevent an electrical current from flowing back into the cells connected to the diode that are not generating electrical power, for example, due to shading or cell failure. An electrical resistance of the shaded cells is greater than that of the bypass diode, and the electrical current is shunted through the diode instead of passing through the cells. This current drain through the shunt could damage the cells in certain situations. Each photovoltaic cell may have a dedicated bypass diode or a group of cells may share one diode.

Furthermore, one or more DC/DC converters may be integrated into module 500. A DC/DC converter may be associated with one photovoltaic module or a set of modules. The DC/DC converter converts an input DC voltage into a higher or lower DC voltage level. The central inverter may also be a part of the module and be connected to a grid or other AC electrical system. For example, several DC/DC converters can be connected to the central inverter by module connectors as described above. The DC/DC converters allow each module, or each set of modules, to operate at its optimum current/voltage regime. The DC/DC converter may operate in a “buck” or “boost” mode, as appropriate. In certain embodiments, a module includes a buck converter connected to a boost converter.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A flexible photovoltaic module comprising:
a front side flexible sealing sheet;
a back side flexible sealing sheet forming a sealed space together with the front side flexible sealing sheet;
one or more flexible photovoltaic cells positioned within the sealed space in between the front side flexible sealing sheet and the back side flexible sealing sheet; and
a first header structure attached to the front side flexible sealing sheet and the back side flexible sealing sheet and enclosing at least a portion of a first edge formed by at least one of the front side flexible sealing sheet and the back side flexible sealing sheet,
the first header structure enclosing one or more electrical leads protruding through the first edge in between the front side flexible sealing sheet and the back side flexible sealing sheet,
the first header structure providing sealing and mechanical support to a first interface between the front side flexible sealing sheet and the back side flexible sealing sheet at the first edge at least around the one or more electrical leads.

2. The flexible photovoltaic module of claim 1, wherein the first header structure encloses the entire first edge.

3. The flexible photovoltaic module of claim 2, wherein the first header structure comprises one or more module connectors positioned at both ends of the first header structure, the one or more module connectors comprising two conductive elements electrically coupled to the flexible photovoltaic cells.

4. The flexible photovoltaic module of claim 1, wherein the first header structure comprises a first module connector comprising a first conductive element electrically coupled to the flexible photovoltaic cells.

5. The flexible photovoltaic module of claim 4, wherein the flexible photovoltaic module comprises a second module connector comprising a second conductive element electrically coupled to the flexible photovoltaic cells.

6. The flexible photovoltaic module of claim 5, wherein the flexible photovoltaic module comprises a return line extending through the flexible photovoltaic module between the first module connector and the second module connector and interconnecting a third conductive element of the first module connector and a fourth conductive element of the second module connector.

7. The flexible photovoltaic module of claim 1, wherein the first header structure encloses at least the portion of the first edge formed by both the front side flexible sealing sheet and the back side flexible sealing sheet.

8. The flexible photovoltaic module of claim 1, wherein the first header structure encloses the entire first edge formed by both the front side flexible sealing sheet and the back side flexible sealing sheet.

9. The flexible photovoltaic module of claim 1, wherein the first header structure is provided on a top surface of the back side flexible sealing sheet such that the first edge is formed by the front side flexible sealing sheet and not by the back side sealing sheet.

10. The flexible photovoltaic module of claim 9, wherein the first header structure encloses the portion of the first edge such that a remaining portion of the first edge remains free from the first header structure.

11. The flexible photovoltaic module of claim 1, wherein the first header structure comprises one or more rigid materials selected from the group consisting of polyethylene terephthalate, polybutylene terephthalate, nylon, polyphenylene sulfide, and polyamide.

12. The flexible photovoltaic module of claim 1, wherein the first header structure comprises interlocking features.

13. The flexible photovoltaic module of claim 1, wherein the first header structure comprises multiple electrical leads attached to the one or more flexible photovoltaic cells and/or one or more conductive elements of a connector supported by the first header structure; and
wherein the header structure comprises one or more bridging connectors interconnecting the one or more multiple electrical leads.

14. The flexible photovoltaic module of claim 1, wherein the first header structure comprises a junction box for installing one or more bridging connectors for interconnecting multiple electrical leads attached to the one or more flexible photovoltaic cells and/or one or more conductive elements of a connector supported by the first header structure.

15. The flexible photovoltaic module of claim 1, wherein the first header structure comprises one or more components selected from the group consisting of: a bypass diode, an inverter, and a DC/DC converter.

16. The flexible photovoltaic module of claim 1, wherein the first header structure comprises an electronic control unit for interconnecting multiple electrical leads attached to the one or more flexible photovoltaic cells and/or one or more conductive elements of a connector supported by the first header structure.

17. The flexible photovoltaic module of claim 1, further comprising a second header structure attached to the front side flexible sealing sheet and the back side flexible sealing sheet and enclosing another portion of the first edge,
the second header structure enclosing one or more second electrical leads protruding through the first edge in between the front side flexible sealing sheet and the back side flexible sealing sheet,
the second header structure providing sealing and mechanical support at a second interface between the front side flexible sealing sheet and the back side flexible sealing sheet at the first edge around the one or more second electrical leads.

18. The flexible photovoltaic module of claim 1, further comprising a second header structure attached to the front side flexible sealing sheet and the back side flexible sealing sheet and enclosing at least a second portion of a second edge formed by at least one of the front side flexible sealing sheet and the back side flexible sealing sheet,
the second header structure enclosing one or more second electrical leads protruding through the second edge in between the front side flexible sealing sheet and the back side flexible sealing sheet,
the second header structure providing sealing and mechanical support at a second interface between the front side flexible sealing sheet and the back side flexible sealing sheet at the second edge around the one or more second electrical leads.

19. The flexible photovoltaic module of claim 18, wherein the first edge is substantially parallel to the second edge.

20. A flexible photovoltaic module comprising:
a front side flexible sealing sheet;
a back side flexible sealing sheet;
one or more flexible photovoltaic cells sealed in between the front side flexible sealing sheet and the back side flexible sealing sheet;
a rigid header structure supporting at least a part of an edge formed by the front side flexible sealing sheet and/or the back side flexible sealing sheet; and
a module connector supported by the header structure, the module connector comprising at least one conductive element electrically connected by an electrical lead to the one or more flexible photovoltaic cells,
wherein the electrical lead extends through a part of the edge supported by the rigid header structure.
